(19) United States
(12) Patent Application Publication
(10) Pub. No.: US 2007/0200736 A1
(43) Pub. Date: Aug. 30, 2007

(54) HAND-HELD DEVICE WITH CHARACTER INPUT ROTARY WHEEL

(75) Inventors: Chin-Feng Chen, Shenzhen (CN); Tay-Yang Lin, Shenzhen (CN); Xiao-Guang Li, Shenzhen (CN); Te-Yao Yeh, Shenzhen (CN); Kuan-Hong Hsieh, Shenzhen (CN)

Correspondence Address: NORTH AMERICA INTELLECTUAL PROPERTY CORPORATION, P.O. BOX 506, MERRIFIELD, VA, 22116, US

(73) Assignee: HON HAI PRECISION INDUSTRY CO., LTD., Taipei Hsien (TW)

(21) Appl. No.: 11/562,964

(22) Filed: Nov. 22, 2006

(30) Foreign Application Priority Data
Feb. 18, 2006 (CN) 200610033843.7

(51) Int. Cl. H03K 17/94

(52) U.S. Cl. 341/35

(57) ABSTRACT

A hand-held device is provided. The hand-held device includes a rotary wheel, a switch, a character region, and a controller. The rotary wheel has a plurality of positioning inputs. The character region includes a plurality of icons corresponding to the positioning inputs. Each icon includes a character. The controller is responsive to operation on the rotary wheel and the switch, and inputs a corresponding character. The above-mentioned rotary wheel can replace keyboard in the hand-held device.

### BACKGROUND OF THE INVENTION

1. Field of the Invention

The present invention relates to a hand-held device, and particularly to a hand-held device with a character input rotary wheel.

2. Description of Related Art

Hand-held devices, for example, mobile phones, and personal digit assistants, usually adopts a keypad to input characters. The keypad typically has fewer keys than a QWERTY keyboard. Furthermore, a key of the keypad is smaller than a key of a normal keyboard. A user usually needs to operate keys on a keypad a plurality of times to input one character. It is uncomfortable to operate small sized keys.

Rotary wheels are used as input apparatus in hand-held devices. For example, U.S. patent application Ser. No. 10/259,159, published May 22, 2003, entitled “Method and apparatus for use of rotational user inputs,” it discloses a media player. The media player includes a display screen and an input device. The display screen displays media items. User rotates the input device to select a media item. U.S. Pat. No. 6,842,169, issued October 19, entitled “Hand-held electronic device with multiple input mode thumbwheel,” it discloses a hand-held electronic device. The electronic device includes a thumbwheel as an auxiliary input device. Rotary wheels are used to select menu items, move cursor, but are unable or inconvenient to use as character input device.

Therefore what is needed is a hand-held device with a character input rotary wheel.

### SUMMARY OF THE INVENTION

A hand-held device is disclosed. The hand-held device includes a rotary wheel, a switch, a character region, and a controller. The rotary wheel has a plurality of positioning inputs. The character region comprises a plurality of icons corresponding to the positioning inputs, wherein each icon comprises a character. The controller is configured for responding to operation on the rotary wheel and the switch, and inputting a corresponding character.

Another kind of hand-held device with character input rotary wheel is disclosed. The hand-held device includes a rotary wheel, a switch, an encoder, a memory, and a controller. The rotary wheel has a plurality of positioning inputs. The encoder is responsive to the rotary wheel and outputs positioning codes. The switch is configured for responding to operation on a user's operation and generates a character input signal. The memory stores characters corresponding to the positioning codes. The controller is configured for receiving the character input signal and inputting a character from the memory according to a positioning code the encoder outputs.

Further features will be described or will become apparent in the course of the following detailed description when read in conjunction with the attached drawings, in which:

### BRIEF DESCRIPTION OF THE DRAWINGS

FIG. 1 is a schematic, front view of a hand-held device with a character input rotary wheel according to a preferred embodiment of the present invention; and

FIG. 2 is a schematic diagram of a hardware infrastructure of the hand-held device of FIG. 1.

### DETAILED DESCRIPTION OF THE INVENTION

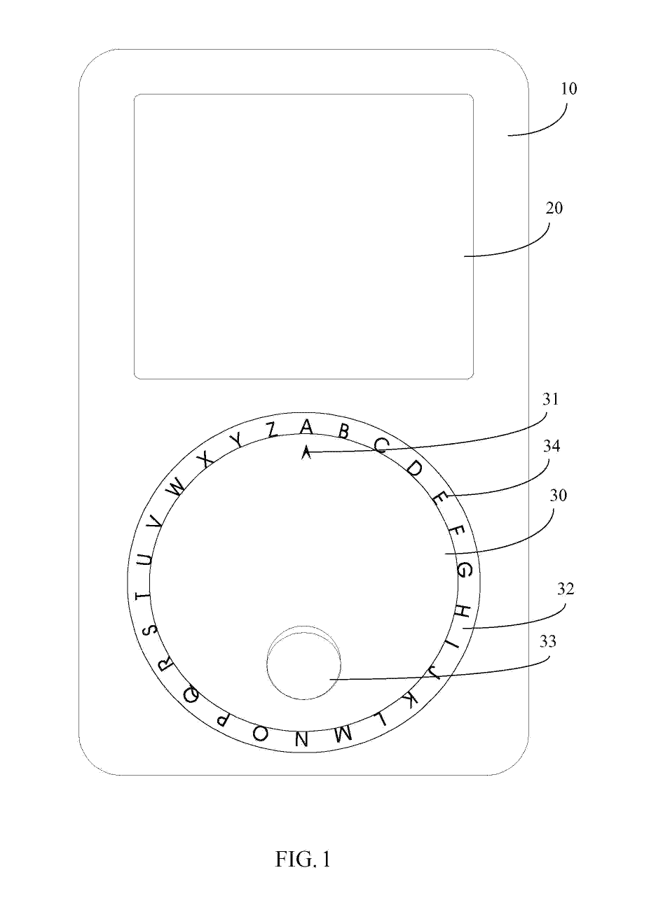

Referring to FIG. 1, a hand-held device is disclosed. The hand-held device 10 includes a display 20 and a rotary wheel 30. The rotary wheel 30 has a plurality of positioning inputs and further has a character region 32 thereon. The character region 32 has a plurality of icons 34 corresponding to the positioning inputs. The icons 34 are arranged in a circle. Each icon 34 may have a corresponding graphical label. The corresponding graphical label can be any character, i.e., number, letter, or symbol. In this exemplary embodiment as shown in FIG. 1, the corresponding graphical label of the icons 34 are letters.

The hand-held device 1 further has an indicator 31. The indicator 31 is positioned between the display 20 and the rotary wheel 30 to indicate the positioning input of the rotary wheel 30; i.e., the rotary wheel 30 is turned (rotated), the indicator 31, thus, rotates correponding the rotary wheel 30, and the positioning input is determined where the indicator 31 aligns with one of the graphical label.

The hand-held device 1 further has a switch 33 for responding to a user's operation and generating a character input signal. The switch 33 can be any appropriate input device. For example, in the embodiment as shown in FIG. 1, the switch 33 is a button. The switch 33 can be positioned at a center of the rotary wheel 30, or off-centered of the rotary wheel 30 as shown in FIG. 1.

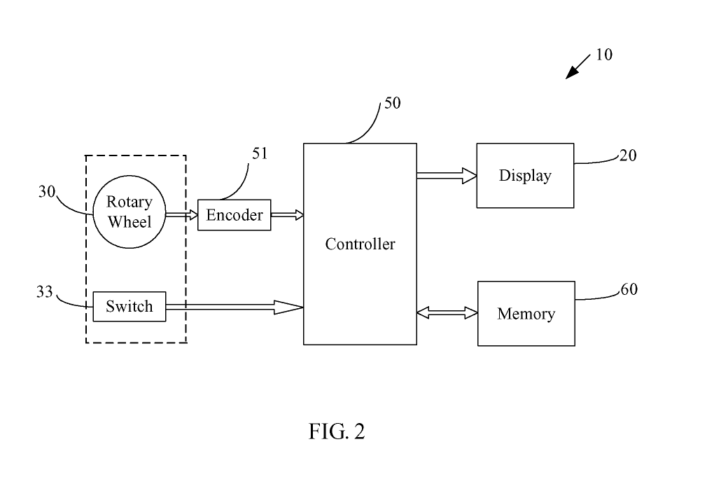

Referring to FIG. 2, a hardware infrastructure of the hand-held device 10 is disclosed. The hand-held device 10 further includes a controller 50, an encoder 51, and a memory 60. The controller 50 is electrically connected to the switch 33, the encoder 51, the display 20, and the memory 60. The encoder 51 is further connected to the rotary wheel 30 and generates a positioning code that corresponds to the positioning input. The memory 60 stores character codes of the character region 32. The controller 50 receives a character input signal from the switch 33, reads a character from the memory 60 according to the positioning code that the encoder 51 outputs, and displays the character on the display 20.

It is understood that the invention may be embodied in other forms without departing from the spirit thereof. Thus, the present examples and embodiments are to be considered in all respects as illustrative and not restrictive, and the invention is not to be limited to the details given herein.

What is claimed is:

1. A hand-held device comprising:
a rotary wheel having a plurality of positioning inputs;
a switch;
a character region comprising a plurality of icons corresponding to the positioning inputs, wherein each icon comprises a character; and
a controller configured for responding to operation on the rotary wheel and the switch, and inputting a corresponding character.

2. The hand-held device of claim 1, further comprising an indicator for indicating the positioning input of the rotary wheel.

3. The hand-held device of claim 2, wherein the indicator is placed out of the rotary wheel.

4. The hand-held device of claim 1, wherein the switch is a button.

5. The hand-held device of claim 4, wherein the button is placed on the rotary wheel.

6. A hand-held device comprising:
a rotary wheel having a plurality of positioning inputs;
a switch;
an encoder configured for responding to the rotary wheel and outputting positioning codes;
a memory storing characters corresponding to the positioning codes; and
a controller configured for responding to operation on the rotary wheel and the switch, and inputting a corresponding character from the memory.

7. The hand-held device of claim 6, further comprising a character region, wherein the character region includes a plurality of icons corresponding to the positioning inputs of the rotary wheel, each icon including a character.

8. The hand-held device of claim 6, further comprising an indicator for indicating the positioning input of the rotary wheel.

9. The hand-held device of claim 8, wherein the indicator is placed out of the rotary wheel.

10. The hand-held device of claim 6, wherein the switch is a button.

11. The hand-held device of claim 10, wherein the button is placed on the rotary wheel.
